(19) United States
(12) Patent Application Publication
(10) Pub. No.: US 2022/0297109 A1
(43) Pub. Date: Sep. 22, 2022

(54) METHOD FOR PRODUCING SILICON-CONTAINING POLYMER COMPOSITION

(71) Applicant: NISSAN CHEMICAL CORPORATION, Tokyo (JP)

(72) Inventor: Takumi OYA, Toyama-shi (JP)

(73) Assignee: NISSAN CHEMICAL CORPORATION, Tokyo (JP)

(21) Appl. No.: 17/638,385

(22) PCT Filed: Sep. 2, 2020
(86) PCT No.: PCT/JP2020/033158

§ 371 Date: Feb. 25, 2022

(30) Foreign Application Priority Data
Sep. 5, 2019 (JP) 2019-162265
Feb. 14, 2020 (JP) 2020-023547

(51) Int. Cl. B01J 39/16; B01J 47/011; B01J 39/05; C08G 77/32

(52) U.S. Cl. CPC B01J 39/16; B01J 47/011; B01J 39/05; C08G 77/32

(57) ABSTRACT

A purification method for a silicon-containing polymer composition capable of reducing metal impurities in a silicon-containing polymer composition to be treated, while suppressing the weight average molecular weight change before and after the treatment, by treating the silicon-containing polymer composition containing the metal impurities with an ion exchange resin having a specific structure; a silicon-containing polymer composition; and a method for producing a semiconductor device. A purification method for a silicon-containing polymer composition reduced in weight average molecular weight change before and after treatment, said method being treating a silicon-containing polymer composition to be treated containing an organic solvent with an gel-type cation exchange resin. The weight average molecular weight change before and after the treatment is 70 or less. The ion exchange resin preferably has a strongly acidic functional group. The total residual amount of 24 metal elements after the ion exchange treatment is 1 ppb or less.

### TECHNICAL FIELD

The present invention relates to an industrially useful method for producing a silicon-containing polymer (a method for purifying metal impurities), in which metal impurities that would cause defects are reduced in a lithography process in manufacture of a semiconductor device.

### BACKGROUND ART

A composition for forming a coating film for lithography used in a lithography process in manufacture of a semiconductor device is required to have reduced metal impurities that would cause minute defects (for example, about 1 to 100 nm, referred to as defects or the like) on a wafer.

A purification method for efficiently obtaining a silicone resin, in which a content of alkali metal ions is small is disclosed (Patent Literature 1).

In addition, purification by distillation can also be used as a method for efficiently removing metal impurities, but in a case where a compound to be purified is solid or has a high boiling point or in a case where a compound to be purified is not stable to heat, the purification by distillation cannot unfortunately be applied.

As a general method for removing metal impurities, a method using an ion exchange resin is also known, but the ion exchange resin acts as a catalyst for promoting polymerization of alkoxysilane, which would undesirably cause promotion of modification of the compound to be purified.

### CITATION LIST

### Patent Literature

Patent Literature 1: JP 2006-342308 A

### SUMMARY OF INVENTION

### Technical Problem

The present invention has been made to solve such problems, and an object of the present invention is to provide a method for producing a silicon-containing polymer composition capable of reducing metal impurities, while suppressing a weight average molecular weight change (ΔMw) before and after treatment of by treating a silicon-containing polymer composition to be treated containing metal impurities with an ion exchange resin having a specific structure, and such a silicon-containing polymer composition.

As a result of intensive studies to achieve the above object, the present inventors have found a method capable of efficiently reducing metal impurities, while suppressing deterioration of a silicon-containing polymer (that is, a weight average molecular weight change (ΔMw)) by treating a silicon-containing polymer composition to be treated containing metal impurities particularly with a gel type strongly acidic cation exchange resin having a sulfonate group as a functional group, thereby completing the present invention.

### Solution to Problem

The present invention encompasses the followings.
[1] A method for producing a silicon-containing polymer composition, characterized by comprising treating a silicon-containing polymer composition to be treated containing an organic solvent with a gel type cation exchange resin, so as to reduce a weight average molecular weight change (ΔMw) of the silicon-containing polymer before and after the treatment.

Preferably, a method for producing a silicon-containing polymer composition, the method comprising treating a silicon-containing polymer composition to be treated, which contains an organic solvent and a silicon-containing polymer, with a gel type cation exchange resin, so as to reduce a weight average molecular weight change (ΔMw) of the silicon-containing polymer in the silicon-containing polymer composition after the treatment relative to the silicon-containing polymer in the silicon-containing polymer composition before the treatment.
[2] The method for producing a silicon-containing polymer composition according to [1], wherein the weight average molecular weight change (ΔMw) is 70 or less.
[3] The method for producing a silicon-containing polymer composition according to [1] or [2], wherein the ion exchange resin has a strongly acidic functional group.
[4] The method for producing a silicon-containing polymer composition according to any one of [1] to [3], wherein the ion exchange resin has a sulfonate group as a functional group.
[5] The method for producing a silicon-containing polymer composition according to any one of [1] to [4], wherein the composition provides a total residual amount of 24 metal elements after the ion exchange treatment of 1 ppb or less.

Preferably, the method for producing a silicon-containing polymer composition according to any one of [1] to [4], wherein the silicon-containing polymer composition to be treated further contains metal impurities, and the silicon-containing polymer composition after the ion exchange treatment has a total amount of Li, Na, Mg, Al, K, Ca, Ti, V, Cr, Mn, Fe, Co, Ni, Cu, Zn, As, Zr, Mo, Ag, Cd, Sn, Ba, W, and Pb of 1 ppb or less.
[6] The method for producing a silicon-containing polymer composition according to any one of [1] to [5], wherein the step of treating is carried out by a batch method or a column flow method.
[7] The method for producing a silicon-containing polymer composition according to any one of [1] to [6], wherein the silicon-containing polymer composition to be treated, that is, the silicon-containing polymer contained in the silicon-containing polymer to be treated, has a weight average molecular weight (Mw) of 800 to 100,000.
[8] A silicon-containing polymer composition, which provides a weight average molecular weight change (ΔMw) of a silicon-containing polymer before and after a treatment with a gel type cation exchange resin of 70 or less, and a total residual amount of 24 metal elements after the ion exchange treatment of 1 ppb or less.

Alternatively, a silicon-containing polymer composition, which provides a total amount of Li, Na, Mg, Al, K, Ca, Ti, V, Cr, Mn, Fe, Co, Ni, Cu, Zn, As, Zr, Mo, Ag, Cd, Sn, Ba, W, and Pb of less than 0.8 ppb.
[9] A silicon-containing resist underlayer film-forming composition comprising the silicon-containing polymer composition according to [8].
[10] A method for manufacturing a semiconductor device, the method comprising: applying the silicon-containing resist underlayer film-forming composition according to [9] onto a semiconductor substrate and baking the applied silicon-containing resist underlayer film-forming composition to form a silicon-containing resist underlayer film; applying a resist film-forming composition onto the underlayer film to form a resist film; exposing the resist film; developing the resist film after the exposure to obtain a patterned resist film; etching the silicon-containing resist underlayer film with the patterned resist film to form a pattern; and processing the semiconductor substrate with the patterned resist film and the silicon-containing resist underlayer film.
[11] A method for producing a silicon-containing resist underlayer film-forming composition, the method comprising treating a silicon-containing polymer composition to be treated containing an organic solvent with a gel type cation exchange resin, so as to reduce a weight average molecular weight change (ΔMw) of a silicon-containing polymer before and after the treatment.
[12] A method for manufacturing a semiconductor device, the method comprising:
applying the silicon-containing resist underlayer film-forming composition produced by the method according to [11] onto a semiconductor substrate and baking the applied silicon-containing resist underlayer film-forming composition to form a silicon-containing resist underlayer film;
applying a resist film-forming composition onto the underlayer film to form a resist film; exposing the resist film; developing the resist film after the exposure to obtain a patterned resist film; etching the silicon-containing resist underlayer film with the patterned resist film to form a pattern; and processing the semiconductor substrate with the patterned resist film and the silicon-containing resist underlayer film.

### Advantageous Effects of Invention

According to the method of the present application, when the ion exchange resin treatment is performed by the method of the present application in production of a silicon-containing polymer composition that is used in a semiconductor lithography process and is required to have high purity, metal impurities in the silicon-containing polymer composition can be reduced, while suppressing modification of a silicon polymer, specifically, a change amount (ΔMw) of a weight average molecular weight (Mw) before and after the treatment.

By the method of the present application, it is possible to provide a silicon-containing resist underlayer film-forming composition, in which metal impurities are reduced and a method for manufacturing a semiconductor device.

### DESCRIPTION OF EMBODIMENTS

<Ion Exchange Resin>

An example of an ion exchange resin includes an ion exchange resin obtained by fixing an ion exchange group to a surface of a porous carrier formed of a styrene-divinylbenzene copolymer. The ion exchange resin is classified into a strongly acidic ion exchange resin, a weakly acidic ion exchange resin, and the like depending on the type of the fixed exchange group of the resin. An example of the strongly acidic ion exchange resin includes a sulfone group. Examples of the weakly acidic ion exchange resin include a carboxyl group, a phosphonic acid group, a phosphinic acid group, an arsenic acid group, and a phenoxide group. In addition, the ion exchange resin is classified into a gel type, a giant network (micro-reticular (MR)) type formed by forming pores in a gel type resin body to have a porosity, and the like depending on physical properties of the carrier.

A catalytic action of the ion exchange resin depends on a contact area between a reactant and a surface of the ion exchange resin and a type of functional group present on the surface of the ion exchange resin. Without being bound by theory, it is presumed that since a gel type ion exchange resin generally has only micropores (pore diameter: several Å to several tens of Å), in a case where a reactant has a large molecular weight such as a polymer, the reactant is difficult to penetrate into the resin pores. It is presumed that since the MR type ion exchange resin has mesopores to macropores (pore diameter: several hundred Å or more), even in a case where a reactant has a large molecular weight such as a polymer, the reactant can penetrate into the pores, a contact area between the polymer or the like and a surface of the ion exchange resin becomes relatively large. The ion exchange resin used in the present invention is preferably a gel type strongly acidic ion exchange resin having a sulfonate group.

The ion exchange resin is not particularly limited as long as it is an ion exchange resin having the present features, that is, a gel type cation exchange resin; and a commercially available ion exchange resin can be used.

Removal of metal impurities by the ion exchange resin may be performed by treating a solution, in which an oil-like or solid-like silicon-containing polymer to be treated is re-dissolved in an organic solvent (a silicon-containing polymer composition to be treated) or a silicon-containing polymer-containing solution subjected to post-treatment after synthesizing a silicon-containing polymer to be treated (a silicon-containing polymer composition to be treated) with an ion exchange resin by a batch method or a column flow method.

The batch method is a method of stirring and mixing a solution to be treated and an ion exchange resin for a certain time and removing the resin by filtration or the like. The column flow method is a method of removing metal impurities from a solution to be treated by passing the solution to be treated through a fixation layer such as a column or a packed column packed with an ion exchange resin.

When comparing the batch method and the column flow method, in general, from the viewpoint of contact efficiency between the solution to be treated and the ion exchange resin, the column flow method can perform treatment with the ion exchange resin in a shorter time, such that the effect of reducing a weight average molecular weight change (ΔMw) is large.

The number of times of treatment is generally one, and may be two or more. A treatment time by the batch method varies depending on the type or amount of the silicon-containing polymer contained in the silicon-containing polymer composition to be treated or the ion exchange resin and the type or amount of the solvent to be used. Similarly, a liquid flow rate in the column flow method varies depending on the type or amount of the silicon-containing polymer contained in the silicon-containing polymer composition to be treated or the ion exchange resin and the type or amount of the solvent to be used. These conditions can be readily optimized by a routine experiment by those skilled in the art.

The amount of the ion exchange resin used in the present invention depends on the type of the silicon-containing polymer contained in the silicon-containing polymer composition to be treated or the type of the organic solvent to be used, and is usually in the range of about 0.01 to 1,000% by mass, preferably 0.1 to 500% by mass, and more preferably 1% by mass to 100% by mass, relative to the amount of the silicon-containing polymer contained in the silicon-containing polymer composition to be treated.

<Silicon-Containing Polymer Contained in Silicon-Containing Polymer Composition to be Treated>

The silicon-containing polymer contained in the silicon-containing polymer composition to be treated that is used in the present invention is not particularly limited, and may be a commercially available silicon-containing polymer or a silicon-containing polymer synthesized by a known method. The silicon-containing polymer may be obtained by polymerizing a commercially available alkoxysilicon compound by a known method (for example, co-condensation by hydrolysis or the like).

Specific examples of the alkoxysilicon compound include compounds represented by the following (2-1) to (2-28) manufactured by Shin-Etsu Chemical Co., Ltd.

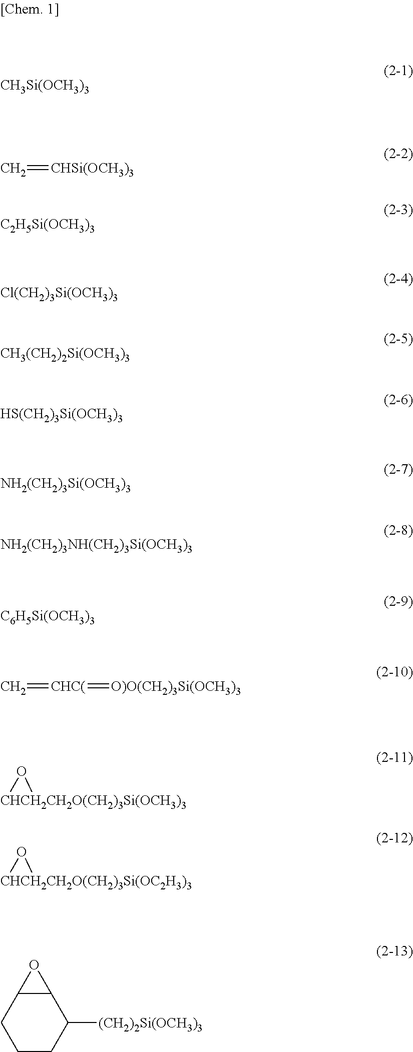

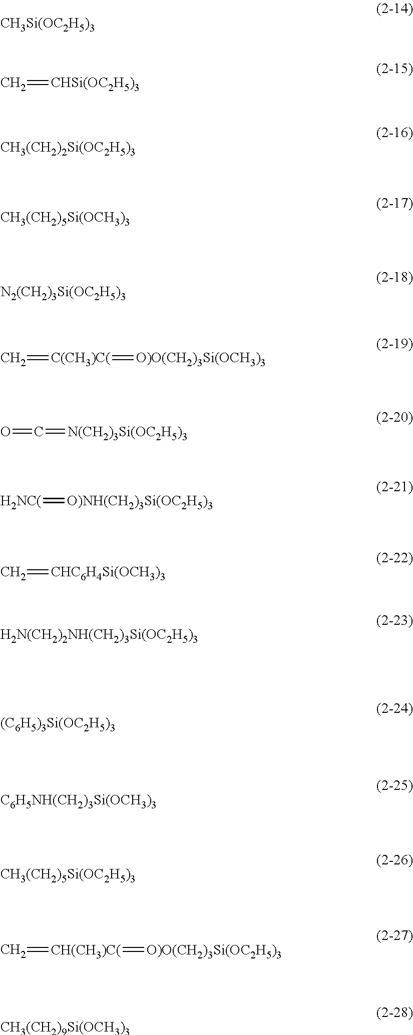

In addition, examples of the silicon-containing polymer include a silicon-containing polymer obtained by a known method (for example, WO 2011/102470 A, WO 2019/003767 A, or the like) and a silicon-containing polymer that can be synthesized in JP 2003-26809 A.

Specific examples of the alkoxysilicon compound include compounds of the following formulas (3-1) to (3-19).

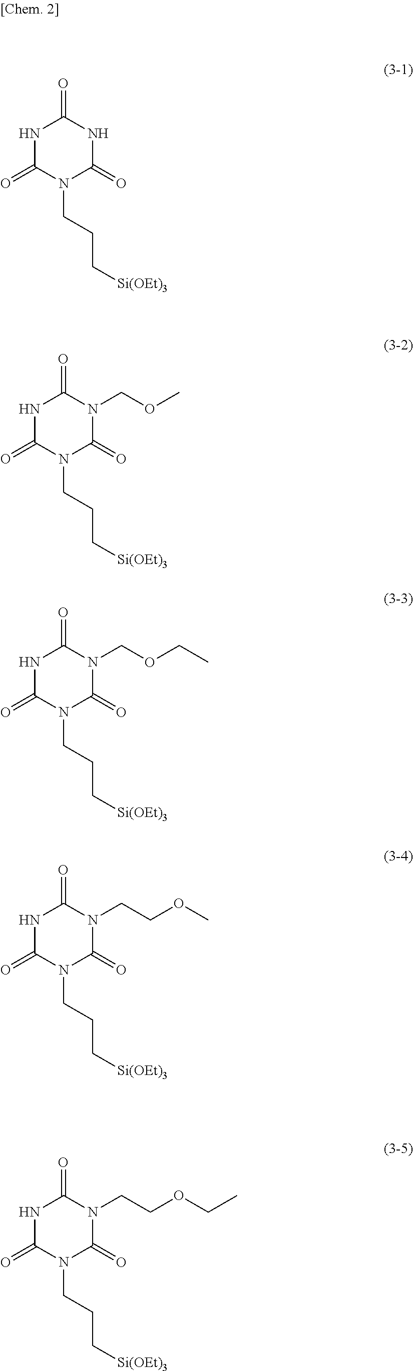

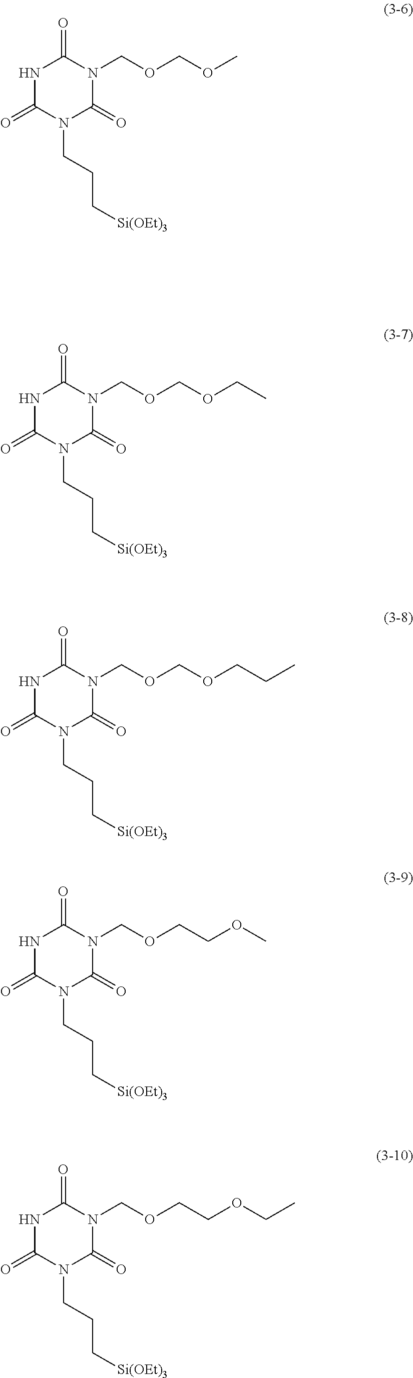

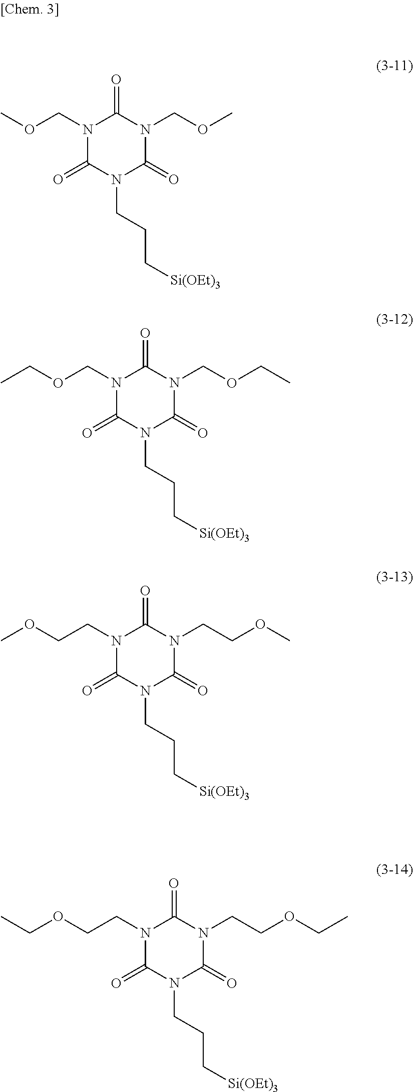

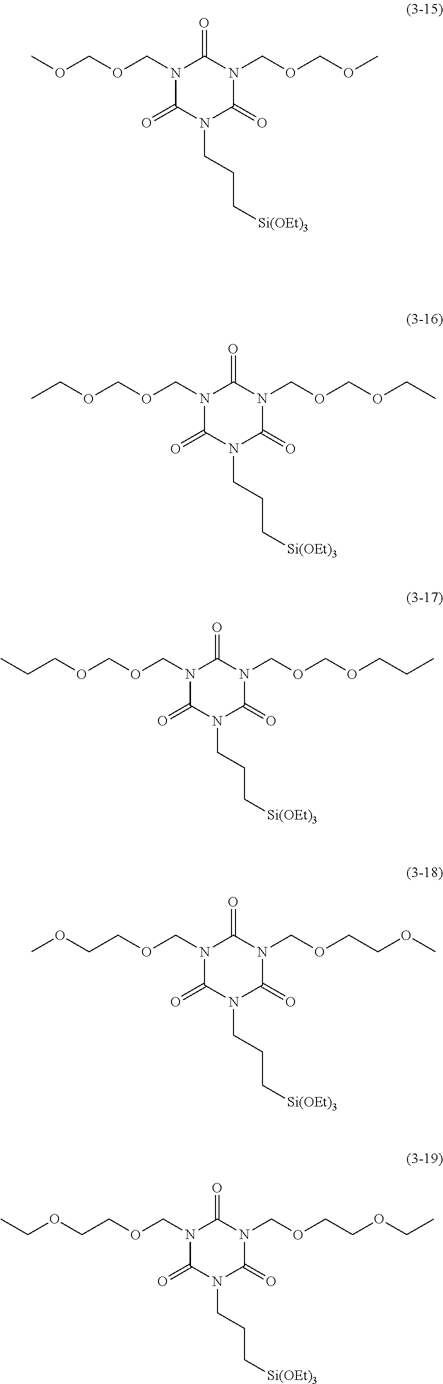

<Organic Solvent>

Examples of the organic solvent contained in the silicon-containing polymer composition to be treated and/or the organic solvent added to the silicon-containing polymer composition to be treated at the time of the ion exchange treatment in the present invention include, but are not limited to, organic solvents mentioned below.

Examples of the organic solvent include ethylene glycol monomethyl ether, ethylene glycol monoethyl ether, methyl cellosolve acetate, ethyl cellosolve acetate, diethylene glycol monomethyl ether, diethylene glycol monoethyl ether, propylene glycol, propylene glycol monomethyl ether, propylene glycol monoethyl ether, propylene glycol monomethyl ether acetate, propylene glycol propyl ether acetate, toluene, xylene, methyl ethyl ketone, methyl isobutyl ketone, cyclopentanone, cyclohexanone, cycloheptanone, cyclopentyl methyl ether, 4-methyl-2-pentanol, methyl 2-hydroxyisobutyrate, ethyl 2-hydroxyisobutyrate, ethyl ethoxyacetate, 2-hydroxyethyl acetate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, 2-heptanone, methoxycyclopentane, anisole, γ-butyrolactone, N-methylpyrrolidone, N,N-dimethylformamide, N,N-dimethylacetamide, n-heptane, hexane, isopropyl ether, diisobutyl ether, diisoamyl ether, tert-butyl methyl ether, cyclopentyl methyl ether, tetrahydrofuran, 2-methyltetrahydrofuran, and 2,5-dimethyltetrahydrofuran. These solvents can be used alone or in combination of two or more thereof.

Of these solvents, propylene glycol monomethyl ether, propylene glycol monoethyl ether, propylene glycol monomethyl ether acetate, ethyl lactate, butyl lactate, cyclohexanone, n-heptane, hexane, toluene, isopropyl ether, diisobutyl ether, diisoamyl ether, tert-butyl methyl ether, cyclopentyl methyl ether, tetrahydrofuran, 2-methyltetrahydrofuran, 2,5-dimethyltetrahydrofuran, and the like are preferable. In particular, propylene glycol monomethyl ether, propylene glycol monoethyl ether, cyclopentyl methyl ether, propylene glycol monomethyl ether acetate, toluene, and isopropyl ether are preferable.

The amount of the organic solvent used is not particularly limited as long as it is an amount in which the silicon-containing polymer to be treated can be sufficiently dissolved, and is generally in the range of about 2 parts by mass to 1,000 parts by mass, and preferably 4 parts by mass to 100 parts by mass, with respect to 100 parts by mass of the silicon-containing polymer to be treated.

The organic solvent contained in the silicon-containing polymer composition to be treated of the present application is preferably 100% of the solvent contained in the composition, but may contain a solvent other than the organic solvent. For example, when the total amount of the composition is taken as 100% by mass, a solvent other the organic solvent (for example, water) may be contained in a proportion of 1% by mass or less.

A weight average molecular weight (Mw) of the silicon-containing polymer contained in the silicon-containing polymer composition to be treated is in the range of generally 800 to 100,000, preferably 800 to 10,000, and more preferably 800 to 5,000. The weight average molecular weight (Mw) is determined by, for example, a GPC method described in Examples. A weight average molecular weight (Mw) change before and after the ion exchange resin treatment is preferably 70 or less. The smaller the weight average molecular weight (Mw) change is, the more preferable it is. The weight average molecular weight (Mw) change is preferably 60 or less, 50 or less, 40 or less, 30 or less, 20 or less, 10 or less, 5 or less, 3 or less, 1 or less, or 0.

A total residual amount of 24 metal elements (Li, Na, Mg, Al, K, Ca, Ti, V, Cr, Mn, Fe, Co, Ni, Cu, Zn, As, Zr, Mo, Ag, Cd, Sn, Ba, W, and Pb) in the silicon-containing polymer composition after the ion exchange resin treatment is preferably 1 ppb or less. The total residual amount of the 24 metal elements can be measured by, for example, inductively coupled plasma mass spectrometry (ICP-MS) described in Examples.

The total residual amount of the 24 metal elements is preferably 0.9 ppb or less. The total residual amount of the 24 metal elements is preferably less than 0.8 ppb or 0.8 ppb or less. The total residual amount of the 24 metal elements is preferably 0.7 ppb or less. The total residual amount of the 24 metal elements is preferably 0.6 ppb or less. The total residual amount of the 24 metal elements is preferably 0.5 ppb or less. The total residual amount of the 24 metal elements is preferably 0.4 ppb or less. The total residual amount of the 24 metal elements is preferably 0.3 ppb or less. The total residual amount of the 24 metal elements is preferably 0.2 ppb or less. The total residual amount of the 24 metal elements is preferably 0.1 ppb or less. The total residual amount of the 24 metal elements is preferably 0.08 ppb or less. The total residual amount of the 24 metal elements is preferably 0.05 ppb or less. The total residual amount of the 24 metal elements is preferably 0.03 ppb or less. The total residual amount of the 24 metal elements is preferably 0.01 ppb or less. The total residual amount of the 24 metal elements is preferably 0 (detection limit or less).

<Silicon-Containing Resist Underlayer Film-Forming Composition>

The silicon-containing resist underlayer film composition of the present application contains a silicon-containing polymer composition treated by the method of the present application. Examples of the silicon-containing polymer contained in the silicon-containing polymer composition to be treated include, but are not limited to, known silicon-containing resist underlayer film-forming compositions disclosed in WO 2019/181873 A, WO 2019/124514 A, WO 2019/082934 A, WO 2019/009413 A, WO 2018/181989 A, WO 2018/079599 A, WO 2017/145809 A, WO 2017/145808 A, and WO 2016/031563 A, and an example thereof includes a silicon-containing polymer (polysiloxane or the like).

Examples of a preferred embodiment of the silicon-containing resist underlayer film-forming composition of the present application include embodiments described in the specification of the above publications.

An example of the silicon-containing polymer contained in the silicon-containing polymer composition to be treated includes polysiloxane contained in a polysiloxane composition for coating disclosed in WO 2016/031563 A. It is a polysiloxane composition for coating containing a hydrolysis condensate of a hydrolyzable silane containing a hydrolyzable silane having 2 to 3 hydrolyzable groups in a proportion of 30 to 100% by mole in all silanes of the polysiloxane composition for coating.

Such a polysiloxane includes hydrolyzable silanes represented by Formula (1):

[Chem. 4]

R¹ₐSi(R²)₄₋ₐ Formula (1)
in Formula (1), R¹ is an alkyl group, an aryl group, a halogenated alkyl group, a halogenated aryl group, an alkoxyaryl group, an alkenyl group, or an organic group having an epoxy group, an acryloyl group, a methacryloyl group, a mercapto group, or a cyano group, and is bonded to a silicon atom by a Si—C bond, R² represents an alkoxy group, an acyloxy group, or a halogen group, and a indicates an integer of 0 to 2,
   and containing a hydrolyzable silane in which a in Formula (1) is 1 or 2 and a hydrolyzable silane in which a in Formula (1) is 0 in proportions of 30 to 100% by mole of and 0 to 70% by mole, respectively, in all silanes.

The resist underlayer film-forming composition or the polysiloxane composition for coating of the present application contains, for example, a hydrolysis condensate of a hydrolyzable silane represented by Formula (1), and a solvent. As an optional component, an acid, water, an alcohol, a curing catalyst, an acid generator, another organic polymer, a light-absorbing compound, a surfactant, and the like can be contained.

A solid content in the polysiloxane composition for coating is, for example, in the range of 0.1 to 50% by mass, 0.1 to 30% by mass, or 0.1 to 25% by mass. Here, the solid content is obtained by removing a solvent component from all components of the polysiloxane composition for coating.

A proportion of the hydrolyzable silane, a hydrolyzate thereof, and a hydrolysis condensate thereof in the solid content is generally 20% by mass or more, and is, for example, in the range of 50 to 100% by mass, 60 to 99% by mass, or 70 to 99% by mass.

The hydrolyzable silane, the hydrolyzate thereof, and the hydrolysis condensate thereof described above may also be used as a mixture thereof. The hydrolyzable silane is hydrolyzed and may be used as a condensate obtained by condensing the obtained hydrolyzate. It is also possible to use a mixture obtained by mixing a partial hydrolyzate or a silane compound, in which hydrolysis is not completely completed with a hydrolysis condensate, when obtaining the hydrolysis condensate. The condensate is a polymer having a polysiloxane structure.

An example of the silicon-containing polymer contained in the silicon-containing polymer composition to be treated includes a hydrolysis condensate obtained by hydrolyzing and condensing a hydrolyzable silane disclosed in WO 2019/082934 A.

The hydrolyzable silane contains a hydrolyzable silane represented by Formula (1-1):

[Chem. 5]

R¹ₐR²_{b}Si(R³)_{4-(a+b)} Formula (1-1)
in Formula (1-1), R¹ represents an organic group having a primary amino group, a secondary amino group, or a tertiary amino group, and is bonded to a silicon atom by a Si—C bond, R² represents an aryl group, a halogenated alkyl group, a halogenated aryl group, an alkoxyaryl group, an alkenyl group, an acyloxyalkyl group, an organic group having an acryloyl group, a methacryloyl group, a mercapto group, an amino group, an amide group, a hydroxyl group, an alkoxy group, an ester group, a sulfonyl group, or a cyano group, or a group obtained by combining these groups, and is bonded to a silicon atom by a Si—C bond, where, R¹ and R² may be bonded to each other to from a ring structure, R³ represents an alkoxy group, an acyloxy group, or a halogen group, a represents an integer of 1, b is an integer of 0 to 2, and a+b represents an integer of 1 to 3,
   and the hydrolysis condensate has an organic group having a salt structure of a counter anion derived from a strong acid and a counter cation derived from a primary ammonium group, a secondary ammonium group, or a tertiary ammonium group.

A preferred embodiment of the hydrolysis condensate conforms to the content described in WO 2019/082934 A.

The alkyl group is a linear or branched alkyl group having 1 to 10 carbon atoms, and examples thereof include a methyl group, an ethyl group, an n-propyl group, an i-propyl group, an n-butyl group, an i-butyl group, an s-butyl group, a t-butyl group, an n-pentyl group, a 1-methyl-n-butyl group, a 2-methyl-n-butyl group, a 3-methyl-n-butyl group, a 1,1-dimethyl-n-propyl group, a 1,2-dimethyl-n-propyl group, a 2,2-dimethyl-n-propyl group, a 1-ethyl-n-propyl group, n-hexyl, a 1-methyl-n-pentyl group, a 2-methyl-n-pentyl group, a 3-methyl-n-pentyl group, a 4-methyl-n-pentyl group, a 1,1-dimethyl-n-butyl group, a 1,2-dimethyl-n-butyl group, a 1,3-dimethyl-n-butyl group, a 2,2-dimethyl-n-butyl group, a 2,3-dimethyl-n-butyl group, a 3,3-dimethyl-n-butyl group, a 1-ethyl-n-butyl group, a 2-ethyl-n-butyl group, a 1,1,2-trimethyl-n-propyl group, a 1,2,2-trimethyl-n-propyl group, a 1-ethyl-1-methyl-n-propyl group, and a 1-ethyl-2-methyl-n-propyl group.

In addition, a cyclic alkyl group may also be used, and examples of a cyclic alkyl group having 1 to 10 carbon atoms include a cyclopropyl group, a cyclobutyl group, a 1-methyl-cyclopropyl group, a 2-methyl-cyclopropyl group, a cyclopentyl group, a 1-methyl-cyclobutyl group, a 2-methyl-cyclobutyl group, a 3-methyl-cyclobutyl group, a 1,2-dimethyl-cyclopropyl group, a 2,3-dimethyl-cyclopropyl group, a 1-ethyl-cyclopropyl group, a 2-ethyl-cyclopropyl group, a cyclohexyl group, a 1-methyl-cyclopentyl group, a 2-methyl-cyclopentyl group, a 3-methyl-cyclopentyl group, a 1-ethyl-cyclobutyl group, a 2-ethyl-cyclobutyl group, a 3-ethyl-cyclobutyl group, a 1,2-dimethyl-cyclobutyl group, a 1,3-dimethyl-cyclobutyl group, a 2,2-dimethyl-cyclobutyl group, a 2,3-dimethyl-cyclobutyl group, a 2,4-dimethyl-cyclobutyl group, a 3,3-dimethyl-cyclobutyl group, a 1-n-propyl-cyclopropyl group, a 2-n-propyl-cyclopropyl group, a 1-i-propyl-cyclopropyl group, a 2-i-propyl-cyclopropyl group, a 1,2,2-trimethyl-cyclopropyl group, a 1,2,3-trimethyl-cyclopropyl group, a 2,2,3-trimethyl-cyclopropyl group, a 1-ethyl-2-methyl-cyclopropyl group, a 2-ethyl-1-methyl-cyclopropyl group, a 2-ethyl-2-methyl-cyclopropyl group, and a 2-ethyl-3-methyl-cyclopropyl group.

The alkenyl group is an alkenyl group having 2 to 10 carbon atoms, and examples thereof include an ethenyl group, a 1-propenyl group, a 2-propenyl group, a 1-methyl-1-ethenyl group, a 1-butenyl group, a 2-butenyl group, a 3-butenyl group, a 2-methyl-1-propenyl group, a 2-methyl-2-propenyl group, a 1-ethylethenyl group, a 1-methyl-1-propenyl group, a 1-methyl-2-propenyl group, a 1-pentenyl group, a 2-pentenyl group, a 3-pentenyl group, a 4-pentenyl group, a 1-n-propylethenyl group, a 1-methyl-1-butenyl group, a 1-methyl-2-butenyl group, a 1-methyl-3-butenyl group, a 2-ethyl-2-propenyl group, a 2-methyl-1-butenyl group, a 2-methyl-2-butenyl group, a 2-methyl-3-butenyl group, a 3-methyl-1-butenyl group, a 3-methyl-2-butenyl group, a 3-methyl-3-butenyl group, a 1,1-dimethyl-2-propenyl group, a 1-i-propylethenyl group, a 1,2-dimethyl-1-propenyl group, a 1,2-dimethyl-2-propenyl group, a 1-cyclopentenyl group, a 2-cyclopentenyl group, a 3-cyclopentenyl group, a 1-hexenyl group, a 2-hexenyl group, a 3-hexenyl group, a 4-hexenyl group, a 5-hexenyl group, a 1-methyl-1-pentenyl group, a 1-methyl-2-pentenyl group, a 1-methyl-3-pentenyl group, a 1-methyl-4-pentenyl group, a 1-n-butylethenyl group, a 2-methyl-1-pentenyl group, a 2-methyl-2-pentenyl group, a 2-methyl-3-pentenyl group, a 2-methyl-4-pentenyl group, a 2-n-propyl-2-propenyl group, a 3-methyl-1-pentenyl group, a 3-methyl-2-pentenyl group, a 3-methyl-3-pentenyl group, a 3-methyl-4-pentenyl group, a 3-ethyl-3-butenyl group, a 4-methyl-1-pentenyl group, a 4-methyl-2-pentenyl group, a 4-methyl-3-pentenyl group, a 4-methyl-4-pentenyl group, a 1,1-dimethyl-2-butenyl group, a 1,1-dimethyl-3-butenyl group, a 1,2-dimethyl-1-butenyl group, a 1,2-dimethyl-2-butenyl group, a 1,2-dimethyl-3-butenyl group, a 1-methyl-2-ethyl-2-propenyl group, a 1-s-butylethenyl group, a 1,3-dimethyl-1-butenyl group, a 1,3-dimethyl-2-butenyl group, a 1,3-dimethyl-3-butenyl group, a 1-i-butylethenyl group, a 2,2-dimethyl-3-butenyl group, a 2,3-dimethyl-1-butenyl group, a 2,3-dimethyl-2-butenyl group, a 2,3-dimethyl-3-butenyl group, a 2-i-propyl-2-propenyl group, a 3,3-dimethyl-1-butenyl group, a 1-ethyl-1-butenyl group, a 1-ethyl-2-butenyl group, a 1-ethyl-3-butenyl group, a 1-n-propyl-1-propenyl group, a 1-n-propyl-2-propenyl group, a 2-ethyl-1-butenyl group, a 2-ethyl-2-butenyl group, a 2-ethyl-3-butenyl group, a 1,1,2-trimethyl-2-propenyl group, a 1-t-butylethenyl group, a 1-methyl-1-ethyl-2-propenyl group, a 1-ethyl-2-methyl-1-propenyl group, a 1-ethyl-2-methyl-2-propenyl group, a 1-i-propyl-1-propenyl group, a 1-i-propyl-2-propenyl group, a 1-methyl-2-cyclopentenyl group, a 1-methyl-3-cyclopentenyl group, a 2-methyl-1-cyclopentenyl group, a 2-methyl-2-cyclopentenyl group, a 2-methyl-3-cyclopentenyl group, a 2-methyl-4-cyclopentenyl group, a 2-methyl-5-cyclopentenyl group, a 2-methylene-cyclopentyl group, a 3-methyl-1-cyclopentenyl group, a 3-methyl-2-cyclopentenyl group, a 3-methyl-3-cyclopentenyl group, a 3-methyl-4-cyclopentenyl group, a 3-methyl-5-cyclopentenyl group, a 3-methylene-cyclopentyl group, a 1-cyclohexenyl group, a 2-cyclohexenyl group, and a 3-cyclohexenyl group.

The aryl group is an aryl group having 6 to 20 carbon atoms, and examples thereof include a phenyl group, an o-methylphenyl group, an m-methylphenyl group, a p-methylphenyl group, an o-chlorophenyl group, an m-chlorophenyl group, a p-chlorophenyl group, an o-fluorophenyl group, a p-mercaptophenyl group, an o-methoxyphenyl group, a p-methoxyphenyl group, a p-aminophenyl group, a p-cyanophenyl group, an a-naphthyl group, a (3-naphthyl group, an o-biphenylyl group, an m-biphenylyl group, a p-biphenylyl group, a 1-anthryl group, a 2-anthryl group, a 9-anthryl group, a 1-phenanthryl group, a 2-phenanthryl group, a 3-phenanthryl group, a 4-phenanthryl group, and a 9-phenanthryl group.

Examples of the organic group having an epoxy group include glycidoxymethyl, glycidoxyethyl, glycidoxypropyl, glycidoxybutyl, and epoxycyclohexyl.

Examples of the organic group having an acryloyl group include acryloylmethyl, acryloylethyl, and acryloylpropyl.

Examples of the organic group having a methacryloyl group include methacryloylmethyl, methacryloylethyl, and methacryloylpropyl.

Examples of the organic group having a mercapto group include ethyl mercapto, butyl mercapto, hexyl mercapto, and octyl mercapto.

Examples of the organic group having a cyano group include cyanoethyl and cyanopropyl.

The alkoxy group is an alkoxy group having a linear, branched, cyclic alkyl moiety having 1 to 20 carbon atoms, examples thereof include a methoxy group, an ethoxy group, an n-propoxy group, an i-propoxy group, an n-butoxy group, an i-butoxy group, an s-butoxy group, a t-butoxy group, an n-pentyloxy group, a 1-methyl-n-butoxy group, a 2-methyl-n-butoxy group, a 3-methyl-n-butoxy group, a 1,1-dimethyl-n-propoxy group, a 1,2-dimethyl-n-propoxy group, a 2,2-dimethyl-n-propoxy group, a 1-ethyl-n-propoxy group, an n-hexyloxy group, a 1-methyl-n-pentyloxy group, a 2-methyl-n-pentyloxy group, a 3-methyl-n-pentyloxy group, a 4-methyl-n-pentyloxy group, a 1,1-dimethyl-n-butoxy group, a 1,2-dimethyl-n-butoxy group, a 1,3-dimethyl-n-butoxy group, a 2,2-dimethyl-n-butoxy group, a 2,3-dimethyl-n-butoxy group, a 3,3-dimethyl-n-butoxy group, a 1-ethyl-n-butoxy group, a 2-ethyl-n-butoxy group, a 1,1,2-trimethyl-n-propoxy group, a 1,2,2-trimethyl-n-propoxy group, a 1-ethyl-1-methyl-n-propoxy group, and a 1-ethyl-2-methyl-n-propoxy group, and examples of the cyclic alkoxy group include a cyclopropoxy group, a cyclobutoxy group, a 1-methyl-cyclopropoxy group, a 2-methyl-cyclopropoxy group, a cyclopentyloxy group, a 1-methyl-cyclobutoxy group, a 2-methyl-cyclobutoxy group, a 3-methyl-cyclobutoxy group, a 1,2-dimethyl-cyclopropoxy group, a 2,3-dimethyl-cyclopropoxy group, a 1-ethyl-cyclopropoxy group, a 2-ethyl-cyclopropoxy group, a cyclohexyloxy group, a 1-methyl-cyclopentyloxy group, a 2-methyl-cyclopentyloxy group, a 3-methyl-cyclopentyloxy group, a 1-ethyl-cyclobutoxy group, a 2-ethyl-cyclobutoxy group, a 3-ethyl-cyclobutoxy group, a 1,2-dimethyl-cyclobutoxy group, a 1,3-dimethyl-cyclobutoxy group, a 2,2-dimethyl-cyclobutoxy group, a 2,3-dimethyl-cyclobutoxy group, a 2,4-dimethyl-cyclobutoxy group, a 3,3-dimethyl-cyclobutoxy group, a 1-n-propyl-cyclopropoxy group, a 2-n-propyl-cyclopropoxy group, a 1-i-propyl-cyclopropoxy group, a 2-i-propyl-cyclopropoxy group, a 1,2,2-trimethyl-cyclopropoxy group, a 1,2,3-trimethyl-cyclopropoxy group, a 2,2,3-trimethyl-cyclopropoxy group, a 1-ethyl-2-methyl-cyclopropoxy group, a 2-ethyl-1-methyl-cyclopropoxy group, a 2-ethyl-2-methyl-cyclopropoxy group, and a 2-ethyl-3-methyl-cyclopropoxy group.

The acyloxy group is the acyloxy group having 2 to 20 carbon atoms, and examples thereof include a methylcarbonyloxy group, an ethylcarbonyloxy group, an n-propylcarbonyloxy group, an i-propylcarbonyloxy group, an n-butylcarbonyloxy group, an i-butylcarbonyloxy group, an s-butylcarbonyloxy group, a t-butylcarbonyloxy group, an n-pentylcarbonyloxy group, a 1-methyl-n-butylcarbonyloxy group, a 2-methyl-n-butylcarbonyloxy group, a 3-methyl-n-butylcarbonyloxy group, a 1,1-dimethyl-n-propylcarbonyloxy group, a 1,2-dimethyl-n-propylcarbonyloxy group, a 2,2-dimethyl-n-propylcarbonyloxy group, a 1-ethyl-n-propylcarbonyloxy group, an n-hexylcarbonyloxy group, a 1-methyl-n-pentylcarbonyloxy group, a 2-methyl-n-pentylcarbonyloxy group, a 3-methyl-n-pentylcarbonyloxy group, a 4-methyl-n-pentylcarbonyloxy group, a 1,1-dimethyl-n-butylcarbonyloxy group, a 1,2-dimethyl-n-butylcarbonyloxy group, a 1,3-dimethyl-n-butylcarbonyloxy group, a 2,2-dimethyl-n-butylcarbonyloxy group, a 2,3-dimethyl-n-butylcarbonyloxy group, a 3,3-dimethyl-n-butylcarbonyloxy group, a 1-ethyl-n-butylcarbonyloxy group, a 2-ethyl-n-butylcarbonyloxy group, a 1,1,2-trimethyl-n-propylcarbonyloxy group, a 1,2,2-trimethyl-n-propylcarbonyloxy group, a 1-ethyl-1-methyl-n-propylcarbonyloxy group, a 1-ethyl-2-methyl-n-propylcarbonyloxy group, a phenylcarbonyloxy group, and a tosylcarbonyloxy group.

Examples of the acyloxyalkyl group include a combination of the alkyl group mentioned above and the following acyloxy group, and examples thereof include an acetoxymethyl group, an acetoxyethyl group, and an acetoxypropyl group.

Examples of the halogen group include fluorine, chlorine, bromine, and iodine.

Examples of the group mentioned above also apply to an alkyl group, an aryl group, an alkoxy group, and a halogen group in a halogenated alkyl group, a halogenated aryl group, and an alkoxyaryl group.

<Method for Manufacturing Semiconductor Device>

Hereinafter, the use of the silicon-containing resist underlayer film-forming composition used in the present invention will be described.

A silicon-containing resist underlayer film is formed by applying the silicon-containing resist underlayer film-forming composition of the present invention onto a substrate (for example, a silicon wafer substrate, a silicon/silicon dioxide coated substrate, a silicon nitride substrate, a glass substrate, an ITO substrate, a polyimide substrate, a low dielectric constant material (low-k material) coated substrate, or the like) used for manufacturing a semiconductor device, and then baking the silicon-containing resist underlayer film-forming composition. The baking conditions are appropriately selected from a baking temperature of 80° C. to 250° C. and a baking time of 0.3 to 60 minutes. Preferably, the baking temperature is 150° C. to 250° C. and the baking time is 0.5 to 2 minutes.

Here, a thickness of the underlayer film to be formed is, for example, in the range of 10 to 1,000 nm, 20 to 500 nm, 50 to 300 nm, or 100 to 200 nm. In the present invention, the silicon-containing resist underlayer film is an EUV resist underlayer film, and a thickness of the silicon-containing resist underlayer film may be in the range of 1 nm to 30 nm, 1 nm to 20 nm, or 1 nm to 5 nm.

Next, for example, a photoresist layer is formed on the silicon-containing resist underlayer film. The photoresist layer may be formed by a known method, that is, applying and baking a photoresist composition solution onto the underlayer film. A thickness of the photoresist is, for example, in the range of 50 to 10,000 nm, 100 to 2,000 nm, or 200 to 1,000 nm. In the present invention, after an organic underlayer film is formed on the substrate, a silicon-containing resist underlayer film used in the present invention is formed on the organic underlayer film, and a photoresist may be further coated thereon. Therefore, even in a case where a pattern width of the photoresist becomes narrower and the photoresist is thinly coated to prevent the pattern from being collapsed, processing of the substrate may be performed by selecting an appropriate etching gas. For example, it is possible to perform processing on the silicon-containing resist underlayer film used in the present invention using a fluorine-based gas having a sufficiently high etching rate with respect to the photoresist as the etching gas, or it is possible to perform processing of the organic underlayer film using an oxygen-based gas having an etching rate sufficiently higher than that of the silicon-containing resist underlayer film used in the present invention as the etching gas, and further, it is possible to perform processing of the substrate using a fluorine-based gas having a sufficiently high etching rate with respect to the organic underlayer film as the etching gas.

The photoresist formed on the silicon-containing resist underlayer film used in the present invention is not particularly limited as long as it is sensitive to light used for exposure. Either a negative photoresist or a positive photoresist may be used. Examples of the photoresist include a positive photoresist consisting of a novolak resin and 1,2-naphthoquinonediazide sulfonic acid ester; a chemically amplified photoresist formed of a binder having a group degradable by an acid to increase an alkali dissolution rate and a photoacid generator; a chemically amplified photoresist formed of a low-molecular-weight compound degradable by an acid to increase an alkali dissolution rate of the photoresist, an alkali-soluble binder, and a photoacid generator; and a chemically amplified photoresist formed of a binder having a group degradable by an acid to increase an alkali dissolution rate, a low-molecular-weight compound degradable by an acid to increase an alkali dissolution rate of the photoresist, and a photoacid generator. Examples thereof include APEX-E (trade name) manufactured by Shipley Company L.L.C, PAR710 (trade name) manufactured by Sumitomo Chemical Co., Ltd., and SEPR430 (trade name) manufactured by Shin-Etsu Chemical Co., Ltd. In addition, an example thereof can include a fluorine-containing atomic polymer-based photoresist as described in Proc. SPIE, Vol. 3999, 330-334 (2000), Proc. SPIE, Vol. 3999, 357-364 (2000), or Proc. SPIE, Vol. 3999, 365-374 (2000).

Next, in the present invention, exposure is performed through a predetermined mask. For the exposure, a KrF excimer laser (wavelength: 248 nm), an ArF excimer laser (wavelength: 193 nm), an F2 excimer laser (wavelength: 157 nm), or the like may be used. After the exposure, post exposure bake may be performed, if necessary. After the exposure, heating is performed under conditions appropriately selected from a heating temperature of 70° C. to 150° C. and a heating time of 0.3 to 10 minutes.

In addition, in the present invention, instead of a photoresist, a resist for electron beam lithography or a resist for EUV lithography may be used as the resist. As the electron beam resist, either a negative type or a positive type may be used. Examples of the photoresist include a chemically amplified resist formed of a binder having a group degradable by an acid generator and an acid to change an alkali dissolution rate; a chemically amplified resist formed of a low-molecular-weight compound degradable by an alkali-soluble binder, an acid generator, and an acid to change an alkali dissolution rate of the resist; a chemically amplified photoresist formed of a binder having a group degradable by an acid generator and an acid to change an alkali dissolution rate and a low-molecular-weight compound degradable by an acid to change an alkali dissolution rate of the resist; a non-chemically amplified resist formed of a binder having a group degradable by electron beam to change an alkali dissolution rate, and a non-chemically amplified resist formed of a binder having a moiety cut by electron beam to change an alkali dissolution rate. Even in a case of using these electron beam resists, a resist pattern can be formed similarly to a case of using a photoresist obtained using an irradiation source as electron beam. In addition, as the EUV resist, a methacrylate resin-based resist may be used.

Next, development is performed with a developer (for example, an alkali developer). Therefore, for example, in a case where a positive photoresist is used, the photoresist of the exposed portion is removed, and a photoresist pattern is formed.

Examples of the developer include aqueous solutions of alkali metal hydroxides such as potassium hydroxide and sodium hydroxide; aqueous solutions of quaternary ammonium hydroxides such as tetramethylammonium hydroxide, tetraethylammonium hydroxide, and choline; and aqueous alkaline solutions, for example, aqueous amine solutions such as ethanolamine, propylamine, and ethylenediamine. Furthermore, a surfactant or the like may be added to the developer. The conditions for the development are appropriately selected from a temperature of 5 to 50° C. and a time of 10 to 600 seconds.

In addition, in the present invention, an organic solvent may be used as a developer. After the exposure, development is performed with a developer (solvent). Therefore, for example, in a case where a positive photoresist is used, the photoresist of a non-exposed portion is removed, and a photoresist pattern is formed.

Examples of the developer include methyl acetate, butyl acetate, ethyl acetate, isopropyl acetate, amyl acetate, isoamyl acetate, ethyl methoxyacetate, ethyl ethoxyacetate, propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentylacetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Furthermore, a surfactant or the like may be added to the developer. The conditions for the development are appropriately selected from a temperature of 5 to 50° C. and a time of 10 to 600 seconds.

Then, the silicon-containing resist underlayer film (intermediate layer) of the present invention is removed using the pattern of the photoresist (upper layer) thus formed as a protective film. Next, the organic underlayer film (underlayer) is removed using the film including the patterned photoresist and the silicon-containing resist underlayer film (intermediate layer) of the present invention as a protective film. Finally, processing of the semiconductor substrate is performed using the patterned silicon-containing resist underlayer film (intermediate layer) of the present invention and an organic underlayer film (underlayer) as protective films.

First, the silicon-containing resist underlayer film (intermediate layer) of the present invention at the portion from which the photoresist is removed is removed by dry etching to expose the semiconductor substrate. In the dry etching of the silicon-containing resist underlayer film of the present invention, gas such as tetrafluoromethane (CF₄), perfluorocyclobutane (C₄F₈), perfluoropropane (C₃F₈), trifluoromethane, carbon monoxide, argon, oxygen, nitrogen, sulfur hexafluoride, difluoromethane, nitrogen trifluoride and chlorine trifluoride, chlorine, or trichloroborane and dichloroborane may be used.

A halogen-based gas is preferably used for dry etching of the silicon-containing resist underlayer film.

In dry etching using a halogen-based gas, it is difficult to remove a photoresist basically formed of an organic substance. On the other hand, the silicon-containing resist underlayer film of the present invention containing a large amount of silicon atoms is quickly removed with the halogen-based gas. Therefore, a decrease in thickness of the photoresist according to dry etching of the silicon-containing resist underlayer film can be suppressed. As a result, the photoresist can be used in a thin film. Dry etching of the silicon-containing resist underlayer film is preferably performed by a fluorine-based gas, and examples of the fluorine-based gas include tetrafluoromethane (CF₄), perfluorocyclobutane (C₄F₈), perfluoropropane (C₃F₈), trifluoromethane, and difluoromethane (CH₂F₂).

Thereafter, the organic underlayer film is removed using the film including the patterned photoresist and the silicon-containing resist underlayer film of the present invention as a protective film. The organic underlayer film (underlayer) is preferably formed by dry etching using an oxygen-based gas. This is because the silicon-containing resist underlayer film of the present invention containing a large amount of silicon atoms is difficult to be removed by dry etching with an oxygen-based gas.

Finally, processing of the semiconductor substrate is performed. The processing of the semiconductor substrate is preferably performed by dry etching with a fluorine-based gas.

Examples of the fluorine-based gas include tetrafluoromethane (CF₄), perfluorocyclobutane (C₄F₈), perfluoropropane (C₃F₈), trifluoromethane, and difluoromethane (CH₂F₂).

In addition, ion implantation may be performed as processing of the substrate. A semiconductor device is manufactured through a step of removing a mask layer with a chemical solution containing hydrogen peroxide after the processing of the substrate. The mask layer is an organic underlayer film including a resist or a silicon-containing resist underlayer film.

In addition, in the present invention, an organic antireflection film may be formed on the upper layer of the silicon-containing resist underlayer film before the photoresist is formed. An antireflection film composition to be used is not particularly limited, and may be arbitrarily selected from the compositions conventionally used in the lithography process, and the antireflection film may be formed by a conventionally used method, for example, application with a spinner or a coater and baking.

In addition, in the present invention, the substrate to which the silicon-containing resist underlayer film-forming composition is applied may have an organic or inorganic antireflection film formed by a CVD method or the like on the surface thereof, and the silicon-containing resist underlayer film of the present invention may also be formed thereon.

In the present invention, the silicon-containing resist underlayer film formed of the silicon-containing resist underlayer film-forming composition may also absorb light depending on a wavelength of the light used in the lithography process. In such a case, it is possible to function as an antireflection film having an effect of preventing reflected light from the substrate. Furthermore, the silicon-containing resist underlayer film used in the present invention may also be used as a layer to prevent an interaction between a substrate and a photoresist, as a layer having a function of preventing an adverse effect on a substrate of a material used for a photoresist or a substance generated during exposure to a photoresist, as a layer having a function of preventing a diffusion of substances generated from a substrate during heating and baking into an upper photoresist, or as a barrier layer for reducing a poisoning effect of a photoresist layer by a semiconductor substrate dielectric layer.

In addition, the silicon-containing resist underlayer film formed of the silicon-containing resist underlayer film-forming composition is applied to a substrate in which via holes used in a dual damascene process are formed, and may be used as a filling material capable of filling the holes without gaps. In addition, the silicon-containing resist underlayer film may also be used as a planarizing material for planarizing a surface of a semiconductor substrate having irregularities.

In addition, the resist underlayer film of the EUV resist may be used for the following purposes in addition to the function as a hard mask. The silicon-containing resist underlayer film-forming composition may be used as an underlayer antireflection film of an EUV resist capable of preventing reflection of exposure light that is not preferable in EUV exposure (wavelength of 13.5 nm), for example, the above-described UV or DUV (ArF light or KrF light) from a substrate or an interface without intermixing with the EUV resist. Reflection may be efficiently prevented in the underlayer of the EUV resist. In a case where the EUV resist underlayer film is used, a process may be performed in the same manner as that of the photoresist underlayer film.

### EXAMPLES

Next, the content of the present invention will be described in detail with reference to Examples, but the present invention is not limited thereto.

<Gel Permeation Chromatography (GPC) Analysis Conditions>

A molecular weight shown in Examples described below is a measurement result measured by GPC, and measurement conditions are as follows.

Apparatus: HLC-8320 GPC (manufactured by Tosoh Corporation)

Column: KF-G (4.6 mmI.D.×100 mm)+KF-803L (8.0 mmI.D.×300 mm)

+KF-802 (8.0 mmI.D.×300 mm)+KF801 (8.0 mmI.D.×300 mm) (manufactured by Showa Denko K. K.)

Eluent: THF (HPLC grade)

Flow rate: 1.0 ml/min

Column temperature: 40° C.

Detector: RI (differential refractometer)

Injection amount: 30 μL

Sample concentration: adjusted to solid content concentration of 1.0%

Dilution solvent: propylene glycol monoethyl ether (PGEE)

Standard sample: polystyrene, molecular weight: 47,200, 13,300, 3,180, 1,390, or 580

Calibration curve preparation method: cubic curve

Exclusion time: 0 min

### <Description of Abbreviations>

### (Organic Solvent)

PGEE: propylene glycol monoethyl ether

PGMEA: propylene glycol monomethyl ether acetate

<Treatment of Silicon-Containing Polymer (A) Composition to be Treated Using Ion Exchange Resin>

### Example 1

To 95 g of a PGEE/PGMEA solution of the silicon-containing polymer (A) (solid content: about 13% by mass) prepared under the conditions of Synthesis Example 3 of WO 2016/031563 A was added ORLITE DS-1 (trade name) manufactured by Organo Corporation as a gel type strongly acidic cation exchange resin, which had been washed with the PGEE/PGMEA solution to replace the water in the resin therewith, in a total amount of 5 g as dry one. The resultant mixture was stirred at room temperature for 24 hours, and the resin was removed by decantation, thereby obtaining a treated solution (purified solution).

A molecular weight and a residual metal amount of the obtained purified solution of silicon-containing polymer (A) were determined by GPC and by inductively coupled plasma mass spectrometry (ICP-MS (Agilent 7500: Agilent Technologies)), respectively. The results of the molecular weight and residual metal amount are shown in Table 1. When 1 mg of metal is dissolved in 1 kg of the silicon-containing polymer solution, the residual metal amount indicates a metal concentration value of 1,000 ppb.

The 24 elements for which the residual metal amount is measured are the following metals: Li, Na, Mg, Al, K, Ca, Ti, V, Cr, Mn, Fe, Co, Ni, Cu, Zn, As, Zr, Mo, Ag, Cd, Sn, Ba, W, and Pb.

### Comparative Example 1

The same treatment was repeated using a strongly acidic cation exchange resin ORLITE DS-4 manufactured by Organo Corporation having an MR type structure in place of the gel type strongly acidic cation exchange resin manufactured by Organo Corporation of Example 1. The results are shown in Table 1.

### Comparative Example 2

The same treatment was repeated using ORLITE DS-7 manufactured by Organo Corporation, which is a mixture of a strongly acidic cation exchange resin having an MR type structure and a strongly basic anion exchange resin having an MR type structure, in place of the gel type strongly acidic cation exchange resin manufactured by Organo Corporation of Example 1. The results are shown in Table 1. The amount of the resin added was set so that the amount of the strongly acidic cation exchange resin in the mixture was equivalent to that in Example 1.

[Table 1]

TABLE 1

| | | Residual metal amount | | |
|---|---|---|---|---|
| | Ion exchange | (total 24 elements) | | |
| | resin | [ppb] | Mw | ΔMw |
| Untreated | — | 2.6 | 1830 | — |
| Example 1 | DS-1 | 0.6 | 1856 | 26 |
| Comparative | DS-4 | 0.8 | 1943 | 113 |
| Example 1 | | | | |
| Comparative | DS-7 | 1.3 | 2206 | 376 |
| Example 2 | | | | |

(*Untreated: the same treatment (stirring at room temperature for 24 hours) as in Example and Comparative Examples was performed without ion exchange resin)

As shown in Table 1, in the case of using the ion exchange resin of Example 1, the residual metal impurities were removed with little change of ΔMw of the silicon-containing polymer, and in the case of using the ion exchange resin of each of Comparative Examples 1 and 2, it was shown that deterioration (change of ΔMw) of the silicon-containing polymer was not practical. It is considered that the modification of the silicon-containing polymer in the ion exchange process is derived from the fact that the ion exchange resin catalyzed the polymerization reaction of the silicon-containing polymer. A catalytic action of the ion exchange resin depends on a contact area between a reactant and a surface of the ion exchange resin and a type of functional group present on the surface of the ion exchange resin. From the results of Example 1 and Comparative Example 1, it is suggested: that because DS-1 is a gel type ion exchange resin having only micropores (pore diameter: several Å to several tens of Å), the silicon-containing polymer, which is a polymer, cannot penetrate into the resin pores; and that because DS-4 is an MR type ion exchange resin having mesopores and macropores (pore diameter: several hundred Å or more), the silicon-containing polymer can also penetrate into the pores, and the contact area between the silicon-containing polymer and the surface of the ion exchange resin becomes relatively large. In addition, the results of Example 1 and Comparative Example 2 suggest that the basic functional group included in the surface of the anion exchange resin has a large catalytic action for promoting the polymerization reaction of the silicon-containing polymer.

### Example 2

A treatment solution (purified solution) was obtained by column flow-type ion exchange using the same ion exchange resin as in Example 1 and a newly produced liquid polymer to be treated. The liquid flow rate of the liquid polymer to be treated was adjusted so that the space velocity (SV [1/h]: space velocity) was 2 relative to the volume of the resin-packed layer in the column, that is, so that the retention time of the liquid to be treated was 30 minutes. In addition, the operation was performed at room temperature. The results of determining the molecular weight and residual metal amount are shown in Table 2.

TABLE 2

| | | Residual metal amount | | |
|---|---|---|---|---|
| | Ion exchange | (total 24 elements) | | |
| | resin | [ppb] | Mw | ΔMw |
| Untreated | — | 3.2 | 1532 | — |
| Example 2 | DS-1 | 0.2 | 1543 | 11 |

(* Untreated: before performing treatment of Example 2)

As shown in Table 2, also in the column flow method, in the case where the ion exchange resin of Example 2 was used, the residual metal impurities were removed, while suppressing the deterioration of the silicon-containing polymer.

### INDUSTRIAL APPLICABILITY

There is provided an industrially useful method for purifying a silicon-containing polymer having reduced metal impurities that would cause defects and used in a lithography process in manufacture of a semiconductor device.

1. A method for producing a silicon-containing polymer composition, comprising treating a silicon-containing polymer composition to be treated containing an organic solvent with a gel type cation exchange resin, so as to reduce a weight average molecular weight change (ΔMw) of the silicon-containing polymer before and after the treatment.

2. The method for producing a silicon-containing polymer composition according to claim 1, wherein the weight average molecular weight change (ΔMw) is 70 or less.

3. The method for producing a silicon-containing polymer composition according to claim 1, wherein the ion exchange resin has a strongly acidic functional group.

4. The method for producing a silicon-containing polymer composition according to claim 1, wherein the ion exchange resin has a sulfonate group as a functional group.

5. The method for producing a silicon-containing polymer composition according to claim 1, wherein the composition provides a total residual amount of 24 metal elements after the ion exchange treatment of 1 ppb or less.

6. The method for producing a silicon-containing polymer composition according to claim 1, wherein the step of treating is carried out by a batch method or a column flow method.

7. The method for producing a silicon-containing polymer composition according to claim 1, wherein the silicon-containing polymer to be treated has a weight average molecular weight (Mw) of 800 to 100,000.

8. A silicon-containing polymer composition, which provides a weight average molecular weight change (ΔMw) of a silicon-containing polymer before and after a treatment with a gel type cation exchange resin of 70 or less, and a total residual amount of 24 metal elements after the ion exchange treatment of 1 ppb or less.

9. A silicon-containing resist underlayer film-forming composition comprising the silicon-containing polymer composition according to claim 8.

10. A method for manufacturing a semiconductor device, the method comprising:
applying the silicon-containing resist underlayer film-forming composition according to claim 9 onto a semiconductor substrate and baking the applied silicon-containing resist underlayer film-forming composition to form a silicon-containing resist underlayer film;
applying a resist film-forming composition onto the underlayer film to form a resist film;
exposing the resist film;
developing the resist film after the exposure to obtain a patterned resist film;
etching the silicon-containing resist underlayer film with the patterned resist film to form a pattern; and
processing the semiconductor substrate with the patterned resist film and the silicon-containing resist underlayer film.
